(19) United States
(12) Patent Application Publication
(10) Pub. No.: US 2026/0227344 A1
(43) Pub. Date: Aug. 6, 2026

(54) PATTERN INSPECTION APPARATUS, FOCUS POSITION ADJUSTMENT METHOD, AND PATTERN INSPECTION METHOD

(71) Applicant: NuFlare Technology, Inc., Yokohama-shi (JP)

(72) Inventors: Ryoichi HIRANO, Setagaya-ku (JP); Yasuhiro YAMASHITA, Yokohama-shi (JP); Toshiaki OTAKI, Yokohama-shi (JP); Yoshitaka YASUI, Yokohama-shi (JP)

(73) Assignee: NuFlare Technology, Inc., Yokohama-shi (JP)

(21) Appl. No.: 19/576,305

(22) Filed: Mar. 24, 2026

Related U.S. Application Data
(63) Continuation of application No. PCT/JP2024/035365, filed on Oct. 3, 2024.

(30) Foreign Application Priority Data
Oct. 10, 2023 (JP) 2023-175426

(51) Int. Cl. G01N 21/956; G01N 21/88; G03F 9/00

(52) U.S. Cl. CPC G01N 21/95607; G01N 21/8806; G03F 9/7026; G01N 2021/95615; G01N 2021/95676

(57) ABSTRACT

According to one aspect of the present invention, a pattern inspection apparatus, includes: an inspection autofocus signal calculation circuit configured to calculate an inspection autofocus signal for acquiring a focus evaluation value equal to or greater than a threshold value for an inspection target substrate formed with a figure pattern, using the autofocus signal and the focus evaluation value for each height position acquired while changing a height position of a pattern formation surface of the inspection target substrate with the inspection target substrate placed on the stage and a correlation data obtained from a evaluation substrate; and an autofocus mechanism configured to adjust the height position of the pattern formation surface of the inspection target substrate to a height position of the pattern formation surface corresponding to a value of the inspection autofocus signal.

### CROSS-REFERENCE TO RELATED APPLICATION

This application is a continuation application based upon and claims the benefit of priority from prior Japanese Patent Application No. 2023-175426 (application number) filed on Oct. 10, 2023 in Japan, and International Application PCT/JP2024/035365, the International Filing Date of which is Oct. 3, 2024. The contents described in JP2023-175426 and PCT/JP2024/035365 are incorporated herein by reference.

### BACKGROUND OF THE INVENTION

### Field of the Invention

One aspect of the present invention relates to a pattern inspection apparatus, a focus position adjustment method, and a pattern inspection method. For example, the invention relates to an apparatus for inspecting pattern defects in an exposure mask used in semiconductor manufacturing and a focus position adjustment method of the apparatus.

### Related Art

In recent years, with the increasing integration and capacity of large scale integrated circuits (LSIs), the circuit pattern linewidths required for semiconductor elements have increasingly decreased. These semiconductor elements are manufactured by exposing and transferring a pattern onto a wafer with a reduction projection exposure apparatus, so-called a stepper, using an original pattern (also referred to as a mask or a reticle; hereinafter collectively referred to as a mask) on which a circuit pattern is formed, to form a circuit.

In addition, for the manufacture of LSIs, which requires a huge manufacturing cost, improving yield is essential. One of the major factors that reduces yield is pattern defects in masks used when exposing and transferring ultrafine patterns onto semiconductor wafers using photolithography technology. In recent years, as the dimensions of LSI patterns formed on semiconductor wafers have become finer, the dimensions that should be detected as pattern defects have also become extremely small. For this reason, there is a need for higher accuracy in pattern inspection apparatuses for inspecting defects in transfer masks used in LSI manufacturing.

As inspection methods, for example, there are “die-to-die inspection”, in which optical image data obtained by imaging the same pattern at different locations on the same mask are compared with each other, and “die-to-database inspection”, in which writing (or “drawing”) data (design data), which is obtained by converting pattern-designed CAD data into an apparatus input format used by a writing apparatus when writing the pattern on a mask, is input to an inspection apparatus, a reference image is generated based on the drawing data, and the reference image is compared with optical images that are measurement data obtained by imaging the pattern.

In such an inspection apparatus, it is necessary to clearly obtain pattern images on a mask that is an inspection target. However, since the optical system of the inspection apparatus has a finite depth of focus, it is necessary to keep the inspection surface of the inspection target within the depth of focus of the optical system during inspection. In other words, it is required to keep the contrast of the captured image within an allowable range. In the inspection apparatus, it is necessary to continuously capture images by scanning the mask while moving a stage. For this reason, adjusting the focus of the optical system by sequentially calculating image contrast during inspection is not practical due to insufficient processing time.

Therefore, in the inspection apparatus, in addition to an inspection optical system for image capturing, an autofocus mechanism is adopted that detects the height-direction displacement of an inspection target with respect to the inspection optical system and adjusts the height position.

With the recent trend toward finer patterns, the wavelength of inspection light has been shortened. Along with this, the depth of focus of the inspection optical system has become shallower. Therefore, while the accuracy of the measurement system of an independent autofocus mechanism installed in the vicinity of the inspection optical system was sufficient in the past, it is now impossible to detect various fluctuation factors (dependence on temperature/mechanical deformation) of the inspection optical system unless in-situ measurement using the inspection optical system itself is performed, making it impossible to perform highly accurate focus adjustment. For this reason, a configuration in which a part of the inspection optical system is used has been adopted as the autofocus mechanism (see Published Unexamined Japanese Patent Application No. 2020-125941, for example).

In the optical system of such an autofocus mechanism, the amount of light passing through each of slits arranged before and after the in-focus position of an image from the mask is measured, and a change in the height position of the mask is measured by calculating a difference value between the two measured amounts of light. Here, an error occurs between the height position at which the difference value between the measured amounts of light becomes zero and the height position at which the image contrast becomes maximum. For this reason, for each inspection target mask, it is required to acquire parameters necessary for autofocus operation at which the image contrast becomes higher. On the other hand, in order to acquire the parameters necessary for autofocus operation at which the image contrast becomes higher, relationship data between the two is required, and it takes time to perform a process for acquiring the relationship data. In order to shorten the inspection time and accordingly improve the throughput, it is required to shorten the time required for the process to acquire the parameters necessary for autofocus operation at which the image contrast becomes higher.

### BRIEF SUMMARY OF THE INVENTION

According to one aspect of the present invention, a pattern inspection apparatus, includes:
a stage, a substrate being placed on the stage;
a drive mechanism configured to move a height position of the stage;
a correlation data creation circuit configured to create, using an autofocus signal used as a parameter for autofocus control for each height position and a focus evaluation value for evaluating a focus position for the each height position, correlation data between the autofocus signal and the focus evaluation value, the autofocus signal and the focus evaluation value being acquired while changing a height position of a pattern formation surface of an evaluation substrate formed with an evaluation pattern with the evaluation substrate placed on the stage;
a storage device configured to store the correlation data;
an inspection autofocus signal calculation circuit configured to calculate an inspection autofocus signal for acquiring a focus evaluation value equal to or greater than a threshold value for an inspection target substrate formed with a figure pattern, using the autofocus signal and the focus evaluation value for each height position acquired while changing a height position of a pattern formation surface of the inspection target substrate with the inspection target substrate placed on the stage and the correlation data obtained from the evaluation substrate;
an autofocus mechanism configured to adjust the height position of the pattern formation surface of the inspection target substrate to a height position of the pattern formation surface corresponding to a value of the inspection autofocus signal;
a sensor configured to capture an optical image of the inspection target substrate by receiving light transmitted through or reflected from the inspection target substrate irradiated with inspection light in a state where the height position of the pattern formation surface of the inspection target substrate has been adjusted to the height position of the pattern formation surface corresponding to the value of the inspection autofocus signal; and
a comparison circuit configured to compare a captured optical image with a reference image.

According to another aspect of the present invention, a focus position adjustment method, includes:
creating, using an autofocus signal used as a parameter for autofocus control for each height position and a focus evaluation value for evaluating a focus position for the each height position, correlation data between the autofocus signal and the focus evaluation value, the autofocus signal and the focus evaluation value being acquired while changing a height position of a pattern formation surface of an evaluation substrate formed with an evaluation pattern with the evaluation substrate placed on the stage;
storing the correlation data in a storage device;
calculating an inspection autofocus signal for acquiring a focus evaluation value equal to or greater than a threshold value for an inspection target substrate formed with a figure pattern, using the autofocus signal and the focus evaluation value for each height position acquired while changing a height position of a pattern formation surface of the inspection target substrate with the inspection target substrate placed on the stage and the correlation data obtained from the evaluation substrate; and
adjusting, in a case of capturing an optical image of the inspection target substrate with a sensor by receiving light transmitted through or reflected from the inspection target substrate irradiated with inspection light, the height position of the pattern formation surface of the inspection target substrate to a height position of the pattern formation surface corresponding to a value of the inspection autofocus signal.

According to yet another aspect of the present invention, a pattern inspection method, includes:
creating, using an autofocus signal used as a parameter for autofocus control for each height position and a focus evaluation value for evaluating a focus position for each height position, correlation data between the autofocus signal and the focus evaluation value, the autofocus signal and the focus evaluation value being acquired while changing a height position of a pattern formation surface of an evaluation substrate formed with an evaluation pattern with the evaluation substrate placed on the stage;
storing the correlation data in a storage device;
calculating an inspection autofocus signal for acquiring a focus evaluation value equal to or greater than a threshold value for an inspection target substrate formed with a figure pattern, using the autofocus signal and the focus evaluation value for each height position acquired while changing a height position of a pattern formation surface of the inspection target substrate with the inspection target substrate placed on the stage and the correlation data obtained from the evaluation substrate;
capturing an optical image of the inspection target substrate with a sensor by receiving light transmitted through or reflected from the inspection target substrate irradiated with inspection light while adjusting the height position of the pattern formation surface of the inspection target substrate to a height position of the pattern formation surface corresponding to a value of the inspection autofocus signal; and
comparing a captured optical image with a reference image and outputting a result of the comparison.

### BRIEF DESCRIPTION OF THE DRAWINGS

FIG. 1 is a configuration diagram showing the configuration of a pattern inspection apparatus according to Embodiment 1;

FIG. 2 is a conceptual diagram for explaining an inspection region in Embodiment 1;

FIG. 3 is a diagram showing an example of a measurement result of the amount of light for autofocus control in a comparative example of Embodiment 1;

FIG. 4 is a diagram showing an example of an autofocus signal in a comparative example of Embodiment 1;

FIG. 5 is a flowchart showing a part of an example of main steps of an inspection method according to Embodiment 1;

FIG. 6 is a flowchart showing the remaining part of the example of the main steps of the inspection method according to Embodiment 1;

FIG. 7 is a block diagram showing an example of the internal configuration of an autofocus control circuit in Embodiment 1;

FIG. 8 is a diagram for explaining an example of a method for calculating the contrast in Embodiment 1;

FIG. 9 is a diagram for explaining another example of the method for calculating the contrast in Embodiment 1;

FIG. 10 is a diagram for explaining an example of a method for calculating the brightness in Embodiment 1;

FIG. 11 is a diagram showing a state in which the focus evaluation value of each autofocus signal value of an evaluation substrate is plotted in Embodiment 1;

FIG. 12 is a diagram showing a state in which the focus evaluation value of each autofocus signal value of an inspection target substrate is plotted in Embodiment 1;

FIG. 13 is a diagram for explaining filter processing in Embodiment 1; and

FIG. 14 is a diagram showing an example of the internal configuration of a comparison circuit in Embodiment 1.

### DETAILED DESCRIPTION OF THE INVENTION

In the following embodiments, there will be provided an inspection apparatus and method capable of acquiring, in a shorter time than before, parameters necessary for the autofocus operation of an inspection target substrate.

### Embodiment 1

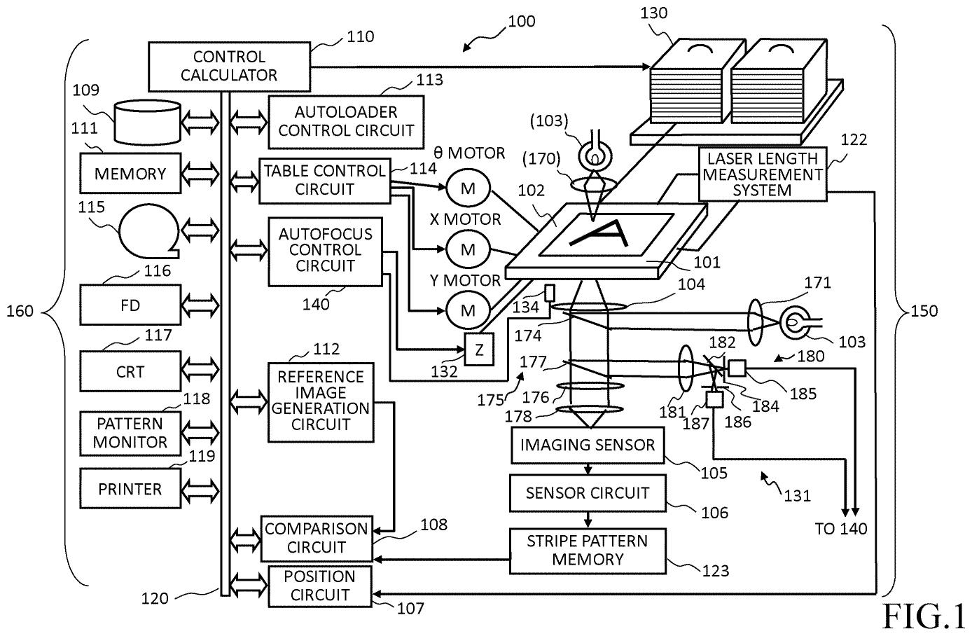

FIG. 1 is a configuration diagram showing the configuration of a pattern inspection apparatus according to Embodiment 1. FIG. 1, an inspection apparatus 100 for inspecting defects in a pattern formed on an inspection target substrate, for example, a mask, includes an optical image acquisition mechanism 150 and a control system circuit 160.

The optical image acquisition mechanism 150 includes a light source 103, a reflection illumination optical system 171, a XYθ table 102 arranged so as to be movable, a magnification optical system 104, a beam splitter 174, a beam splitter 177, a collimator lens 176, an imaging optical system 178, an autofocus mechanism 131, an imaging sensor 105, a sensor circuit 106, a stripe pattern memory 123, a laser length measurement system 122, and an autoloader 130. When performing a transmission inspection using transmitted light, a transmission illumination optical system 170 is further arranged. When performing only a reflection inspection using reflected light without performing a transmission inspection, the transmission illumination optical system 170 may be omitted. When performing both a transmission inspection and a reflection inspection simultaneously, an imaging sensor (not shown) may be further provided, so that the imaging sensor 105 captures images for reflection inspection and the additional imaging sensor captures images for transmission inspection.

The autofocus mechanism 131 includes an autofocus optical system 180, a light amount sensor 185 (first light amount sensor), a light amount sensor 187 (second light amount sensor), a Z drive mechanism 132, and a position sensor 134.

The autofocus optical system 180 includes an imaging optical system 181, a beam splitter 182, a slit plate 184, and a slit plate 186. The autofocus optical system 180 guides light transmitted through or reflected from the substrate to the light amount sensor 185 and the light amount sensor 187. The beam splitter 182 is arranged in front of the focus position. The slit plate 184 is arranged at a front focus position and receives light transmitted through the beam splitter 182. The light amount sensor 185 measures the amount of light passing through the slit plate 184 arranged at the front focus position. The slit plate 186 is arranged at a rear focus position and receives light split by the beam splitter 182. The light amount sensor 187 measures the amount of light passing through the slit plate 186 arranged at the rear focus position.

An inspection target substrate 101 transported from the autoloader 130 is placed on the XYθ table 102. As the inspection target substrate 101, for example, a photomask for exposure used to transfer a pattern onto a semiconductor substrate such as a wafer is included. In addition, a figure pattern that is an inspection target is formed on this photomask. The substrate 101 is placed on the XYθ table 102, for example, with a pattern formation surface facing downward. The XYθ table 102 is an example of a stage.

As the imaging sensor 105, a line sensor or a two-dimensional sensor is used. For example, it is preferable to use a time delay integration (TDI) sensor. The TDI sensor includes a plurality of photosensor elements arranged in a two-dimensional manner. For each photosensor element, a predetermined image accumulation time is set when an image is captured. In the TDI sensor, outputs of a plurality of photosensor elements aligned in the scan direction are integrated and output. The plurality of photosensor elements aligned in the scan direction capture the same pixel while shifting the timing in accordance with the movement of the XYθ table 102. When a line sensor is used, the plurality of photosensor elements are arranged so that the plurality of photosensor elements are aligned in a direction perpendicular to the scan direction.

In the control system circuit 160, a control calculator 110 that controls the entire inspection apparatus 100 is connected, through a bus 120, to a position circuit 107, a comparison circuit 108, a reference image generation circuit 112, an autoloader control circuit 113, a table control circuit 114, an autofocus control circuit 140, a magnetic disk drive 109, a memory 111, a magnetic tape drive 115, a flexible disk drive (FD) 116, a CRT 117, a pattern monitor 118, and a printer 119. In addition, the imaging sensor 105 is connected to the stripe pattern memory 123, and the stripe pattern memory 123 is connected to the comparison circuit 108. In addition, the reference image generation circuit 112 is connected to the comparison circuit 108.

The output of the position sensor 134 is connected to the autofocus control circuit 140. In addition, the outputs of the light amount sensors 185 and 187 are connected to the autofocus control circuit 140.

In addition, a series of “~ circuits”, such as the position circuit 107, the comparison circuit 108, the reference image generation circuit 112, the autoloader control circuit 113, the table control circuit 114, and the autofocus control circuit 140, each include a processing circuit. Examples of such a processing circuit include an electric circuit, a computer, a processor, a circuit board, a quantum circuit, and a semiconductor device. Each circuit may be configured using the same processing circuit (one processing circuit), or may be configured using different processing circuits (separate processing circuits). For example, a series of “~ circuits”, such as the position circuit 107, the comparison circuit 108, the reference image generation circuit 112, the autoloader control circuit 113, the table control circuit 114, and the autofocus control circuit 140, may be configured and executed by the control calculator 110. Input data required for the position circuit 107, the comparison circuit 108, the reference image generation circuit 112, the autoloader control circuit 113, the table control circuit 114, and the autofocus control circuit 140 or calculation results thereof are stored, as needed, in a memory (not shown) within each circuit or in the memory 111. Input data required for the control calculator 110 or calculation results thereof are stored, as needed, in a memory (not shown) within the control calculator 110 or in the memory 111. A program for executing a processor and the like may be recorded on a record carrier body storing therein a processing procedure in a computer readable and executable form, such as the magnetic disk drive 109, the magnetic tape drive 115, the FD 116, or a read only memory (ROM).

The inspection apparatus 100 includes, as an inspection optical system 175, a reflection inspection optical system and/or a transmission inspection optical system. The light source 103, the reflection illumination optical system 171, the beam splitter 174, the magnification optical system 104, the XYθ table 102, the collimator lens 176, and the imaging optical system 178 form a high-magnification reflection inspection optical system. Alternatively, the light source 103, the transmission illumination optical system 170, the XYθ table 102, the magnification optical system 104, the collimator lens 176, and the imaging optical system 178 from a high-magnification transmission inspection optical system.

In addition, the XYθ table 102 is driven by the table control circuit 114 under the control of the control calculator 110. The XYθ table 102 can be moved by a drive system such as three-axis (X-Y-θ) motors for driving in an X direction, a Y direction, and a θ direction. As these X motor, Y motor, and θ motor, for example, step motors can be used. The XYθ table 102 can be moved in a horizontal direction and a rotational direction by the motors of the respective X, Y, and θ axes. The XYθ table 102 is an example of a stage. Then, the movement position of the substrate 101 placed on the XYθ table 102 is measured by the laser length measurement system 122 and supplied to the position circuit 107. In addition, the transport of the substrate 101 from the autoloader 130 to the XYθ table 102 and the transport of the substrate 101 from the XYθ table 102 to the autoloader 130 are controlled by the autoloader control circuit 113.

In addition, the XYθ table 102 is driven in a z direction by the Z drive mechanism 132 that is controlled by the autofocus control circuit 140. As the Z drive mechanism 132, for example, a piezoelectric element or a step motor is preferably used. In addition, the height position of the XYθ table 102 is measured by the position sensor 134, and a measurement result is output to the autofocus control circuit 140.

Writing data (design data) that is a basis for forming a pattern on the inspection target substrate 101 is input from outside the inspection apparatus 100 and stored in the magnetic disk drive 109. In the writing data, a plurality of figure patterns are defined, and each figure pattern is usually configured by a combination of a plurality of element figures. In addition, each figure pattern may be configured by a single element figure. On the inspection target substrate 101, corresponding patterns are formed based on the respective figure patterns defined in the writing data.

Here, in FIG. 1, components necessary for explaining Embodiment 1 are shown. It goes without saying that the inspection apparatus 100 may include other components that are normally required.

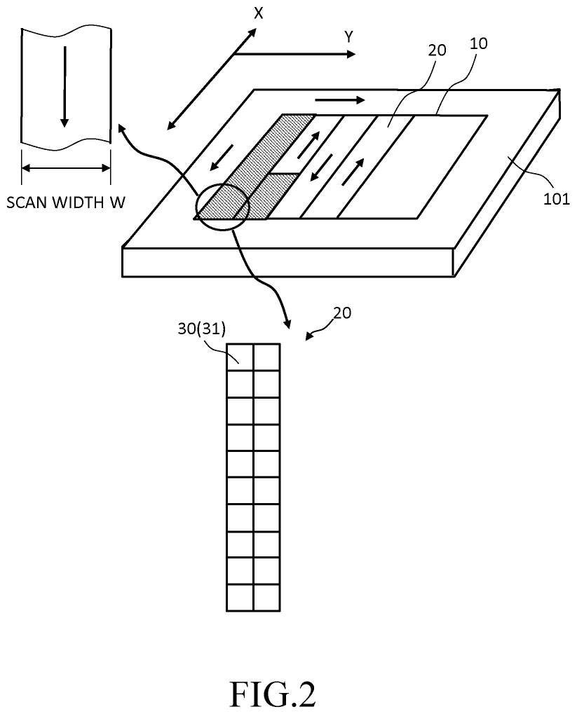

FIG. 2 is a conceptual diagram for explaining an inspection region in Embodiment 1. As shown in FIG. 2, an inspection region 10 (entire inspection region) of the substrate 101 is virtually divided, for example in the Y direction, into a plurality of strip-shaped inspection stripes 20 each having a scan width W of the imaging sensor 105. Then, the inspection apparatus 100 acquires an image (stripe region image) for each inspection stripe 20. For each inspection stripe 20, an image of a figure pattern arranged within the inspection stripe 20 is captured using laser light (inspection light) in a longitudinal direction (X direction) of the stripe region. In addition, in order to prevent missing images, it is preferable that the plurality of inspection stripes 20 are set so that adjacent inspection stripes 20 overlap each other with a predetermined margin width.

Optical images are acquired while the imaging sensor 105 is continuously moved relatively in the X direction by the movement of the XYθ table 102. The imaging sensor 105 continuously captures optical images having a scan width W as shown in FIG. 2. In Embodiment 1, after capturing an optical image of one inspection stripe 20, the imaging sensor 105 moves in the Y direction to the position of the next inspection stripe 20 and then moves in the opposite direction to continuously capture optical images having the scan width W in the same manner. That is, image capturing is repeated in forward (FWD) and backward (BWD) directions that are opposite to each other in an outward path and a return path.

In addition, in actual inspection, as shown in FIG. 2, a stripe region image of each inspection stripe 20 is divided into images (frame images 31) of a plurality of rectangular frame regions 30. Then, inspection is performed for each frame image 31 of the frame region 30. For example, the stripe region image is divided into frame images each having a size of 512×512 pixels. Therefore, a reference image to be compared with the frame image 31 of the frame region 30 is also generated for each frame region 30 in the same manner.

Here, the imaging direction is not limited to the repetition of forward (FWD) and backward (BWD). Imaging may be performed from only one direction. For example, FWD-FWD may be repeated. Alternatively, BWD-BWD may be repeated.

As described above, the inspection apparatus 100 includes, in addition to the inspection optical system 175 (reflection inspection optical system and/or transmission inspection optical system), the autofocus mechanism 131 that detects the height-direction displacement of the substrate 101, which is an inspection target, with respect to the inspection optical system 175.

Here, as pattern miniaturization progresses, the wavelength of inspection light has been shortened, and accordingly the depth of focus of the inspection optical system 175 has become shallower. As a result, while the accuracy of an independent measurement system installed in the vicinity of the inspection optical system was sufficient in the past, it is now impossible to detect various fluctuation factors (dependence on temperature/mechanical deformation) of the inspection optical system unless in-situ measurement using the inspection optical system itself is performed, making it impossible to perform highly accurate focus adjustment.

That is, the autofocus mechanism is required to have a function of detecting (monitoring) changes in the state of the inspection optical system in addition to changes in signal output (sensor output) according to changes in mask height. In order for the autofocus optical system to use an inspection optical system, the approach has evolved from a method that adopts an objective lens (with dual wavelength aberration correction) adapted to the original measurement light source (red laser) to a method that provides an optical system using DUV light, which is inspection light, in response to demands for further higher precision of the objective lens.

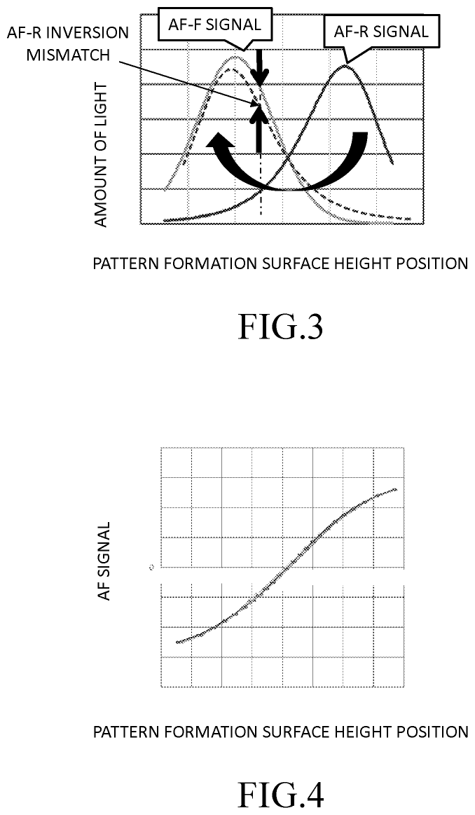

FIG. 3 is a diagram showing an example of a measurement result of the amount of light for autofocus control in a comparative example of Embodiment 1. In the comparative example shown in FIG. 3, signal changes of a light amount signal AF-F at the front focus position and a light amount signal AF-R at the rear focus position with respect to the pattern formation surface height position of the mask measured using a confocal optical system are shown. Ideally, the light amount signal AF-F and the light amount signal AF-R show changes that are left-right symmetrical with respect to their maximum values. In addition, ideally, the light amount signal AF-F and the light amount signal AF-R show the same distribution. Therefore, ideally, the light amount signal AF-F and the light amount signal AF-R change symmetrically with respect to the focus position. In such a case, a value (autofocus signal: AF signal) obtained by dividing the difference between the light amount signal AF-F and the light amount signal AF-R by their sum changes linearly with changes in the pattern formation surface height position of the mask.

Therefore, the height position of the mask pattern formation surface is changed to calculate the autofocus signal and the contrast of the obtained image for each height position. Then, a correlation graph between the autofocus signal and the contrast of the image is created, and the autofocus signal at which the contrast becomes maximum is calculated as the autofocus signal for the focus position. In the autofocus mechanism, the autofocus signal is fed back as a stage displacement signal, and the stage height is adjusted so that the autofocus signal becomes an autofocus signal for the focus position.

However, the light reaching the slit plates 184 and 186 may show different distribution changes when the height of the mask pattern formation surface is changed, due to astigmatism caused by performance variations of optical elements, misalignment in optical adjustment, and the like. As a result, the light amount signals that pass through the slit plates 184 and 186 and are measured by the light amount sensors 185 and 187 may not change symmetrically with respect to the maximum value of changes in the mask height position. In the comparative example shown in FIG. 3, a case is shown in which a deviation occurs when the light amount signal AF-R at the rear focus position is inverted and superimposed on the light amount signal AF-F at the front focus position. In this manner, the light amount signal AF-F and the light amount signal AF-R do not change symmetrically with respect to the focus position.

FIG. 4 is a diagram showing an example of an autofocus signal in a comparative example of Embodiment 1. The autofocus signal can be defined as a value obtained by dividing the difference between the light amount signal AF-F and the light amount signal AF-R by their sum. If the light amount signal AF-F and the light amount signal AF-R change left-right symmetrically with respect to their maximum values and both have the same distribution, the autofocus signal is proportional to changes in the pattern formation surface height position of the mask. However, as shown in the comparative example of FIG. 4, the autofocus signal does not change linearly and is not proportional to changes in the pattern formation surface height position of the mask. Therefore, the autofocus signal generates a non-linear error with respect to changes in the pattern formation surface height position of the mask.

For this reason, a correlation graph between the autofocus signal and the image contrast becomes a left-right asymmetric graph. Such a correlation graph is obtained for each inspection target substrate, and the autofocus signal at which the contrast of the correlation graph becomes maximum is used as an inspection autofocus signal for that inspection target substrate. However, since the graph is left-right asymmetric and complex, the approximation error becomes large when the number of measurement points is small. Therefore, when the number of measurement points is small, a highly accurate inspection autofocus signal cannot be obtained. On the other hand, if measurements are performed at a large number of measurement points for each inspection target substrate, it takes a long time to perform a process for acquiring the inspection autofocus signal. In order to shorten the inspection time and accordingly improve the throughput, it is required to shorten the time required for the process to acquire the inspection autofocus signal at which the image contrast becomes higher.

Therefore, in Embodiment 1, instead of acquiring such a highly accurate correlation graph using the inspection target substrate, such a correlation graph is acquired in advance, for example, at the time of manufacturing and assembling the inspection apparatus 100, using an evaluation substrate. Then, during actual inspection, the correlation graph obtained for the evaluation substrate is fitted to results at a small number of measurement points obtained for the inspection target substrate, thereby calculating an inspection autofocus signal for the inspection target substrate. Hereinafter, a specific description will be given.

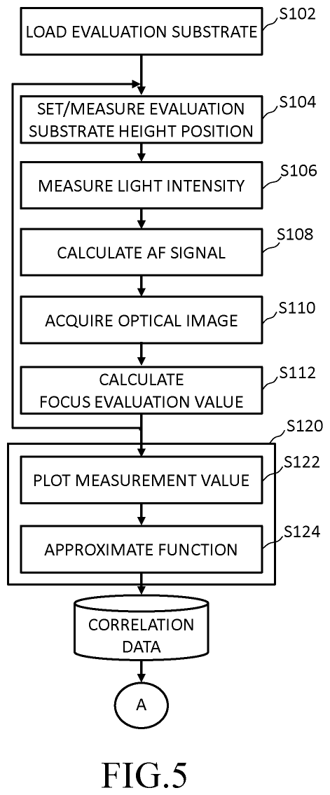

FIG. 5 is a flowchart showing a part of an example of main steps of the inspection method according to Embodiment 1.

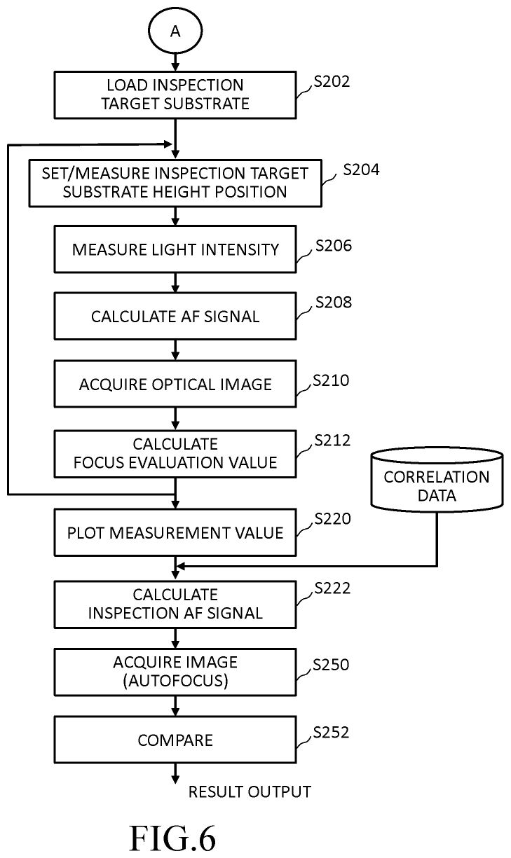

FIG. 6 is a flowchart showing the remaining part of the example of the main steps of the inspection method according to Embodiment 1.

In FIGS. 5 and 6, the inspection method according to Embodiment 1 performs a series of steps, including an evaluation substrate loading step (S102), an evaluation substrate height position setting and measurement step (S104), a light intensity measurement step (S106), an autofocus signal calculation step (S108), an optical image acquisition step (S110), a focus evaluation value calculation step (S112), a correlation data creation step (S120), an inspection target substrate loading step (S202), an inspection target substrate height position setting and measurement step (S204), a light intensity measurement step (S206), an autofocus signal calculation step (S208), an optical image acquisition step (S210), a focus evaluation value calculation step (S212), a measurement value plotting step (S220), an inspection autofocus signal calculation step (S222), an image acquisition (autofocus control) step (S250), and a comparison step (S252).

The correlation data creation step (S120) includes, as internal steps, a measurement value plotting step (S122) and a function approximation step (S124).

In the evaluation substrate loading step (S102), the evaluation substrate transferred from the autoloader 130 is placed on the XYθ table 102.

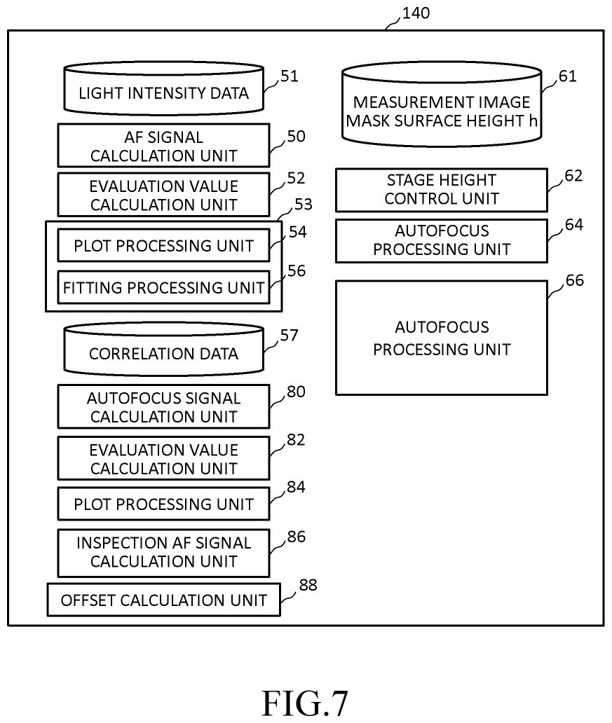

FIG. 7 is a block diagram showing an example of the internal configuration of an autofocus control circuit in Embodiment 1. In FIG. 7, storage devices 51, 57, and 61 such as magnetic disk drives, an autofocus signal calculation unit 50, an evaluation value calculation unit 52, a correlation data creation unit 53, a stage height control unit 62, an autofocus signal calculation unit 64, an autofocus processing unit 66, an autofocus signal calculation unit 80, an evaluation value calculation unit 82, a plot processing unit 84, an inspection autofocus signal calculation unit 86, and an offset calculation unit 88 are arranged in the autofocus control circuit 140.

A plot processing unit 54 and a fitting processing unit 56 are arranged in the correlation data creation unit 53.

A series of “~ units”, such as the autofocus signal calculation unit 50, the evaluation value calculation unit 52, the correlation data creation unit 53 (the plot processing unit 54 and the fitting processing unit 56), the stage height control unit 62, the autofocus signal calculation unit 64, the autofocus processing unit 66, the autofocus signal calculation unit 80, the evaluation value calculation unit 82, the plot processing unit 84, the inspection autofocus signal calculation unit 86, and the offset calculation unit 88, each include a processing circuit. Examples of such a processing circuit include an electric circuit, a computer, a processor, a circuit board, a quantum circuit, and a semiconductor device. In addition, for the respective “~ units”, a common processing circuit (the same processing circuit) may be used. Alternatively, different processing circuits (separate processing circuits) may be used. Input data required for the autofocus signal calculation unit 50, the evaluation value calculation unit 52, the correlation data creation unit 53 (the plot processing unit 54 and the fitting processing unit 56), the stage height control unit 62, the autofocus signal calculation unit 64, the autofocus processing unit 66, the autofocus signal calculation unit 80, the evaluation value calculation unit 82, the plot processing unit 84, the inspection autofocus signal calculation unit 86, and the offset calculation unit 88 or calculation results thereof are stored, as needed, in a memory (not shown) within the autofocus control circuit 140 or in the memory 111.

In the evaluation substrate height position setting and the measurement step (S104), under the control of the stage height control unit 62, the Z drive mechanism 132 drives the height position of the XYθ table 102 to variably set the evaluation substrate height position (pattern formation surface height position). In addition, the evaluation substrate height position is measured by the position sensor 134. The evaluation substrate height position h measured by the position sensor 134 is output to the autofocus control circuit 140 and stored in the storage device 61.

An evaluation pattern is formed on the evaluation substrate. As the evaluation pattern, for example, a line-and-space pattern can be used. For example, a 1:1 line-and-space pattern is used. Alternatively, a hole pattern having a predetermined pattern density (for example, 50%) can be used. The pattern linewidth d of these evaluation patterns can be defined by the following Expression (1) using the light source wavelength λ of the inspection apparatus 100 and the numerical aperture NA of the optical system. It is preferable to set k to a value greater than 1. For example, it is preferable to set k to a value in the range of 1<k<10.

$$λ / ( 2 NA ) \leq d \leq k ( λ / ( 2 NA ) ) \qquad ( 1 )$$

In the light intensity measurement step (S106), in a state where the evaluation substrate height position is controlled to a height position hi, the amount of light, which has been transmitted through or reflected from the evaluation substrate irradiated with inspection light, at the front focus position is measured by the light amount sensor 185. Similarly, the amount of light at the rear focus position is measured by the light amount sensor 187. Specifically, the operation is as follows. i indicates an index.

Laser light (for example, DUV light) having a wavelength in the ultraviolet region or shorter, which serves as inspection light, is emitted from the appropriate light source 103 and the beam splitter 174 is irradiated with the laser light by the reflection illumination optical system 171. The irradiated laser light is reflected by the beam splitter 174 and is directed to the evaluation substrate by the magnification optical system 104. The light reflected from the evaluation substrate passes through the magnification optical system 104 and the beam splitter 174 to be emitted to the beam splitter 177. The light split by the beam splitter 177 is incident on the autofocus optical system 180.

The light incident on the autofocus optical system 180 is refracted in a converging direction by the imaging optical system 181 to be emitted to the beam splitter 182. The light transmitted through the beam splitter 182 is partially restricted by the slit plate 184 at the front focus position, and the amount of light passing through the slit plate 184 is measured by the light amount sensor 185. The light split by the beam splitter 182 is partially restricted by the slit plate 186 at the rear focus position, and the amount of light passing through the slit plate 186 is measured by the light amount sensor 187. In this manner, it is possible to measure the amount of light at the front focus position and the amount of light at the rear focus position at the height position hi. The respective light amount data pieces (light intensity data pieces) of the measured amount of light at the front focus position and the measured amount of light at the rear focus position at the height position hi are stored in the storage device 51.

In the autofocus signal calculation step (S108), the autofocus signal calculation unit 50 calculates an autofocus signal εi, which is used as a parameter for autofocus control when the evaluation substrate height position is the height position hi. The autofocus signal εi is defined by the following Equation (2) using the amount of light Ai at the front focus position and the amount of light Bi at the rear focus position. i indicates an index.

$$ε i = ( Ai - Bi ) / ( Ai + Bi ) \qquad ( 2 )$$

The value of the autofocus signal εi is stored, for example, in the storage device 51 in association with the height position hi.

In the optical image acquisition step (S110), the optical image acquisition mechanism 150 captures an optical image of the evaluation substrate by receiving light, which has been transmitted through or reflected from the evaluation substrate irradiated with inspection light, at the set height position hi through the inspection optical system 175 using the imaging sensor 105 in a state where the evaluation substrate is placed on the XYθ table 102. Specifically, the operation is as follows.

The optical image acquisition mechanism 150 scans, with laser light (inspection light), the inspection stripe 20 including a preset frame region 30 of the evaluation substrate, thereby capturing a stripe region image with the imaging sensor 105. Specifically, the operation is as follows. The XYθ table 102 is moved to a position where the inspection stripe 20, which is the target of the evaluation substrate, can be imaged. In transmission inspection, laser light (for example, DUV light) having a wavelength in the ultraviolet region or shorter, which serves as inspection light, is emitted from the appropriate light source 103 and is directed to the transmission illumination optical system 170. The transmission illumination optical system 170 irradiates the pattern formed on the evaluation substrate with laser light. In other words, the transmission illumination optical system 170 illuminates the evaluation substrate on which the pattern is formed. The light transmitted through the evaluation substrate passes through the magnification optical system 104 and the collimator lens 176, and is formed as an optical image on the imaging sensor 105 (an example of a sensor) and incident on it by the imaging optical system 178.

Alternatively, in reflection inspection, laser light (for example, DUV light) having a wavelength in the ultraviolet region or shorter, which serves as inspection light, is emitted from the appropriate light source 103 and is directed to the reflection illumination optical system 171. The reflection illumination optical system 171 irradiates the beam splitter 174 the laser light. The irradiated laser light is reflected by the beam splitter 174 and the evaluation substrate is irradiated with the laser light by the magnification optical system 104. The light reflected from the evaluation substrate passes through the magnification optical system 104, the beam splitter 174, and the collimator lens 176, and is formed as an optical image on the imaging sensor 105 and incident on it by the imaging optical system 178.

The imaging sensor 105 captures an optical image of the evaluation substrate.

The image of the pattern formed on the imaging sensor 105 is photoelectrically converted by each photosensor element of the imaging sensor 105, and is further A/D (analog-to-digital) converted by the sensor circuit 106. Then, pixel value data of the inspection stripe 20 to be measured is stored in the stripe pattern memory 123. The measurement data (pixel data) is, for example, 8-bit unsigned data, and represents the brightness gradation (amount of light) of each pixel. Then, among the inspection stripe images, a frame image 31 (measurement image) of a preset frame region 30 is output to the autofocus control circuit 140 and stored in the storage device 61.

In the focus evaluation value calculation step (S112), the evaluation value calculation unit 52 calculates a focus evaluation value from the obtained image. As the focus evaluation value, for example, one of the contrast and brightness obtained from the optical image is used.

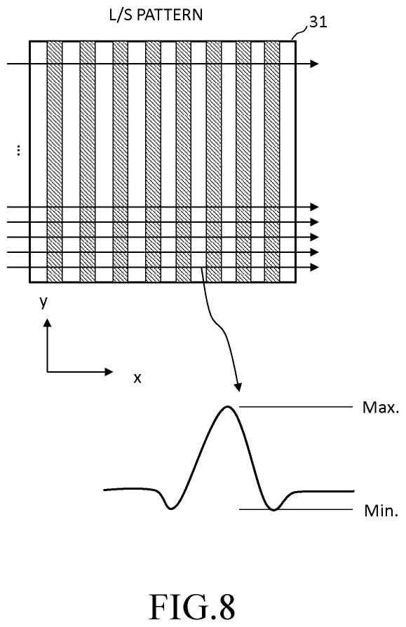

FIG. 8 is a diagram for explaining an example of a method for calculating the contrast in Embodiment 1. In the example shown in FIG. 8, a case is shown in which a line-and-space pattern, which is an example of an evaluation pattern, appears in the measurement image. In such a case, the contrast of gradation data is calculated for each of a plurality of lines in a direction (x direction) perpendicular to a direction (y direction) in which the line pattern (or space pattern) extends. The contrast C can be defined by the following Equation (3) using the maximum and minimum values of the gradation data.

$$C = ( maximum value - minimum value ) / ( maximum value + minimum value ) \qquad ( 3 )$$

Then, as the contrast of such an image, for example, an average value of the contrasts of all the lines is calculated. In addition, in order to reduce measurement variations, it is preferable to use the average value of the contrasts of as many lines as possible, but the lines are not limited to all the lines.

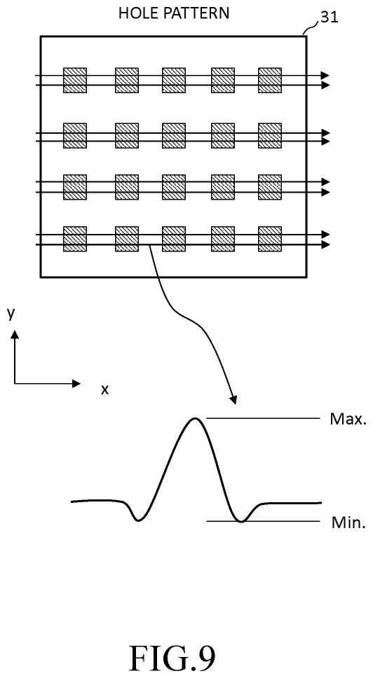

FIG. 9 is a diagram for explaining another example of the method for calculating the contrast in Embodiment 1. In the example shown in FIG. 9, a case is shown in which a hole pattern, which is another example of the evaluation pattern, appears in the measurement image. In such a case, the contrast of gradation data is calculated for each of a plurality of lines in, for example, the x direction perpendicular to the y direction, at a plurality of positions in, for example, the y direction overlapping the hole pattern. The contrast C can be defined by the above-described Equation (3) using the maximum and minimum values of the gradation data.

Then, as the contrast of such an image of the evaluation substrate, for example, an average value of the contrasts of all the lines is calculated.

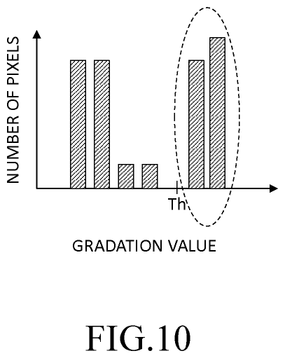

FIG. 10 is a diagram for explaining an example of a method for calculating the brightness in Embodiment 1. In the example shown in FIG. 10, a histogram example is shown in which the vertical axis indicates the number of pixels (frequency) and the horizontal axis indicates the gradation value. Such a histogram is created using all pixels in the measurement image. Then, the total number of pixels having gradation values equal to or greater than a threshold value Th is defined as the brightness of the image.

Then, the process returns to the evaluation substrate height position setting and measurement step (S104), and while changing the evaluation substrate height position, the respective steps from the evaluation substrate height position setting and measurement step (S104) to the focus evaluation value calculation step (S112) are repeated. As a result, an optical image of the evaluation substrate is acquired for each height position while changing the height position of the pattern formation surface of the evaluation substrate. In addition, an AF signal is acquired for each height position. Then, the evaluation value calculation unit 52 calculates, for each height position, a focus evaluation value for evaluating the focus position while changing the height position of the pattern formation surface of the evaluation substrate on which the figure pattern is formed. The AF signal and the focus evaluation value are acquired at four or more height positions. More preferably, the AF signal and the focus evaluation value are acquired at ten or more height positions.

In the correlation data creation step (S120), the correlation data creation unit 53 creates correlation data between the AF signal and the focus evaluation value by using, for each height position, the autofocus signal (AF signal) used as a parameter for autofocus control and the focus evaluation value for evaluating the focus position, which are acquired while changing the height position of the pattern formation surface of the evaluation substrate with the evaluation pattern formed thereon in a state where the evaluation substrate is placed on the XYθ table 102 (stage). Hereinafter, a specific description will be given.

In the measurement value plotting step (S122), the plot processing unit 54 plots the focus evaluation value for each AF signal value acquired for each height position on a coordinate system in which the vertical axis indicates the focus evaluation value and the horizontal axis indicates the AF signal.

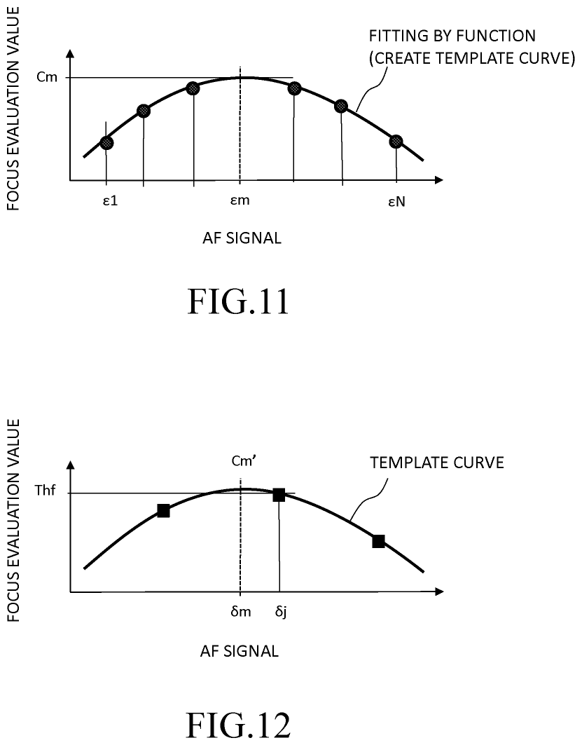

FIG. 11 is a diagram showing a state in which the focus evaluation value of each autofocus signal value of the evaluation substrate is plotted in Embodiment 1. In FIG. 11, the vertical axis indicates the focus evaluation value. The horizontal axis indicates the autofocus signal value. In the example shown in FIG. 11, focus evaluation values at six autofocus signal values ε1, εi, εN are shown. Since the autofocus signal is used, the graph is not left-right symmetrical, resulting in non-linear errors.

In the function approximation step (S124), the fitting processing unit 56 approximates the plotted focus evaluation value for each autofocus signal value with a convex polynomial function. As shown in the example of FIG. 11, a function obtained by approximating the AF signal and the focus evaluation value for each height position, in which the focus evaluation value becomes a maximum value Cm when the AF signal value is εm, is used as correlation data.

In the above example, a case has been described in which an approximated function is used as the correlation data; however, the invention is not limited to this. For example, it is also preferable that a numerical sequence of AF signals and focus evaluation values for each height position is used as the correlation data.

The obtained correlation data is stored in the storage device 57. As described above, the graph shape obtained from the correlation data of the evaluation substrate is used as a template for the inspection target substrate.

In the inspection target substrate loading step (S202), the inspection target substrate 101 transported from the autoloader 130 is placed on the XYθ table 102.

In the inspection target substrate height position setting and measurement step (S204), under the control of the stage height control unit 62, the Z drive mechanism 132 drives the height position of the XYθ table 102 to variably set the inspection target substrate height position (pattern formation surface height position). In addition, the inspection target substrate height position is measured by the position sensor 134. The inspection target substrate height position h measured by the position sensor 134 is output to the autofocus control circuit 140 and stored in the storage device 61.

A figure pattern to be inspected is formed on the inspection target substrate 101. For example, a line-and-space pattern or a hole pattern is formed.

In the light intensity measurement step (S206), in a state where the inspection target substrate height position is controlled to a height position hj, the amount of light, which has been transmitted through or reflected from the inspection target substrate 101 irradiated with inspection light, at the front focus position is measured by the light amount sensor 185. Similarly, the light amount at the rear focus position is measured by the light amount sensor 187. Specifically, the operation is as follows. j indicates an index.

Laser light (for example, DUV light) having a wavelength in the ultraviolet region or shorter, which serves as inspection light, is emitted from the appropriate light source 103 and the beam splitter 174 is irradiated with the laser light by the reflection illumination optical system 171. The irradiated laser light is reflected by the beam splitter 174 and is directed to the inspection target substrate 101 by the magnification optical system 104. The light reflected from the inspection target substrate 101 passes through the magnification optical system 104 and the beam splitter 174 to be emitted to the beam splitter 177. The light split by the beam splitter 177 is incident on the autofocus optical system 180.

The light incident on the autofocus optical system 180 is refracted in a converging direction by the imaging optical system 181 to be emitted to the beam splitter 182. The light transmitted through the beam splitter 182 is partially restricted by the slit plate 184 at the front focus position, and the amount of light that has passed through the slit plate 184 is measured by the light amount sensor 185. The light split by the beam splitter 182 is partially restricted by the slit plate 186 at the rear focus position, and the amount of light that passes through the slit plate 186 is measured by the light amount sensor 187. In this manner, it is possible to measure the amount of light at the front focus position and the amount of light at the rear focus position at the height position hj. The respective light amount data pieces (light intensity data pieces) of the measured amount of light at the front focus position and the measured amount of light at the rear focus position at the height position hj are stored in the storage device 51.

In the autofocus signal calculation step (S208), the autofocus signal calculation unit 80 calculates an AF signal δj when the inspection target substrate height position is a height position hj. The AF signal δj is defined by Equation (4) using the amount of light Aj at the front focus position and the amount of light Bj at the rear focus position. j indicates an index.

$$δj = ( Aj - Bj ) / ( Aj + Bj ) \qquad ( 4 )$$

The value of the AF signal δj is stored, for example, in the storage device 51 in association with the height position hj.

In the optical image acquisition step (S210), the optical image acquisition mechanism 150 captures an optical image of the inspection target substrate 101 by receiving light, which has been transmitted through or reflected from the inspection target substrate 101 irradiated with inspection light, at the set height position hj through the inspection optical system 175 using the imaging sensor 105 in a state where the inspection target substrate 101 is placed on the XYθ table 102.

The optical image acquisition mechanism 150 scans, with laser light (inspection light), the inspection stripe 20 including a preset frame region 30 of the inspection target substrate 101, thereby capturing a stripe region image with the imaging sensor 105. Specifically, the operation is as follows. The XYθ table 102 is moved to a position where the inspection stripe 20, which is the target of the inspection target substrate 101, can be imaged. In transmission inspection, laser light (for example, DUV light) having a wavelength in the ultraviolet region or shorter, which serves as inspection light, is emitted from the appropriate light source 103 and is directed to the transmission illumination optical system 170. The transmission illumination optical system 170 irradiates the pattern formed on the inspection target substrate 101 with the laser light. In other words, the transmission illumination optical system 170 illuminates the inspection target substrate 101 on which the pattern is formed. The light transmitted through the inspection target substrate 101 passes through the magnification optical system 104 and the collimator lens 176, and is formed as an optical image on the imaging sensor 105 (an example of a sensor) and incident on it by the imaging optical system 178.

Alternatively, in reflection inspection, laser light (for example, DUV light) having a wavelength in the ultraviolet region or shorter, which serves as inspection light, is emitted from the appropriate light source 103 and is directed to the reflection illumination optical system 171. The reflection illumination optical system 171 irradiates the beam splitter 174 with the laser light. The irradiated laser light is reflected by the beam splitter 174 and inspection target substrate 101 is irradiated with the laser light by the magnification optical system 104. The light reflected from the inspection target substrate 101 passes through the magnification optical system 104, the beam splitter 174, and the collimator lens 176, and is formed as an optical image on the imaging sensor 105 and incident on it by the imaging optical system 178.

The imaging sensor 105 captures an optical image of the inspection target substrate 101.

The image of the pattern formed on the imaging sensor 105 is photoelectrically converted by each photosensor element of the imaging sensor 105, and is further A/D (analog-to-digital) converted by the sensor circuit 106. Then, pixel value data of the inspection stripe 20 to be measured is stored in the stripe pattern memory 123. The measurement data (pixel data) is, for example, 8-bit unsigned data, and represents the brightness gradation (amount of light) of each pixel. Then, among the inspection stripe images, a frame image 31 (measurement image) of a preset frame region 30 is output to the autofocus control circuit 140 and stored in the storage device 61.

In the focus evaluation value calculation step (S212), the evaluation value calculation unit 82 calculates a focus evaluation value from the obtained image. As the focus evaluation value, for example, one of the contrast and brightness obtained from the optical image is used. Here, the same value as the focus evaluation value of the evaluation substrate is used. For example, contrast is used. Also, for the inspection target substrate 101, as in the case described in FIG. 8, the contrast of gradation data is calculated for each of a plurality of lines in a direction (x direction) perpendicular to a direction (y direction) in which the line pattern (or space pattern) extends. The contrast C can be defined by Equation (3) using the maximum and minimum values of the gradation data.

Then, as the contrast of the image of the inspection target substrate 101, for example, the average value of the contrast of all the lines is calculated. In addition, in order to reduce measurement variations, it is preferable to use the average value of the contrasts of as many lines as possible, but the lines are not limited to all the lines. As a pattern for which the average contrast value is to be calculated, for example, it is sufficient to use a pattern having a size close to that of the evaluation pattern of the evaluation substrate, which matches the performance of the inspection apparatus 100.

And/Alternatively, when a hole pattern, which is another example of the inspection target pattern, appears in the measurement image, as in the case shown in FIG. 9, the contrast of gradation data is calculated for each of a plurality of lines in, for example, the x direction perpendicular to the y direction, at a plurality of positions in, for example, the y direction overlapping the hole pattern. The contrast C can be defined by the above-described Equation (3) using the maximum and minimum values of the gradation data.

Then, as the contrast of such an image of the inspection target substrate 101, for example, an average value of the contrasts of all the lines is calculated. The method for calculating the brightness is as described with reference to FIG. 10.

Then, the process returns to the inspection target substrate height position setting and measurement step (S204), and while changing the inspection target substrate height position, the respective steps from the inspection target substrate height position setting and measurement step (S204) to the focus evaluation value calculation step (S212) are repeated. As a result, an optical image of the inspection target substrate 101 is acquired for each height position while changing the height position of the pattern formation surface of the inspection target substrate 101. In addition, an AF signal is acquired for each height position. Then, the evaluation value calculation unit 82 calculates, for each height position, a focus evaluation value for evaluating the focus position while changing the height position of the pattern formation surface of the evaluation substrate on which the figure pattern is formed. Here, the AF signal and the focus evaluation value for each height position of the inspection target substrate 101 are acquired at three or more different height positions hj, which is fewer than when acquiring correlation data for the evaluation substrate.

In the measurement value plotting step (S220), the plot processing unit 84 plots the focus evaluation value of each acquired AF signal value in a coordinate system in which the vertical axis indicates the focus evaluation value and the horizontal axis indicates the AF signal.

FIG. 12 is a diagram showing a state in which the focus evaluation value of each autofocus signal value of an inspection target substrate is plotted in Embodiment 1. FIG. 12, the vertical axis indicates the focus evaluation value. The horizontal axis indicates the autofocus signal value. In the example shown in FIG. 12, focus evaluation values at three autofocus signal values δj are shown.

Here, since the AF signal value indicating the height of the inspection target substrate changes due to temperature changes of the apparatus, and the contrast evaluation value is affected by phase changes of the inspection target substrate, the combination of the AF signal and the focus evaluation value obtained for the inspection target substrate 101 does not necessarily numerically match the combination of the AF signal and the focus evaluation value obtained for the evaluation substrate. However, the pattern linewidth of the figure pattern to be inspected, which is formed on the inspection target substrate 101, is generally set to a size that matches the performance of the inspection apparatus 100. Therefore, this exhibits behavior similar to that of the evaluation pattern.

In the inspection autofocus signal calculation step (S222), the inspection autofocus signal calculation unit 86 calculates an inspection AF signal δm at which a focus evaluation value equal to or greater than a threshold value is obtained for the inspection target substrate 101, using the AF signal and the focus evaluation values for each height position acquired while changing the height position of the pattern formation surface of the inspection target substrate 101, on which the figure pattern is formed and which is placed on the XYθ table 102 (stage), together with correlation data for the evaluation substrate. A specific description will be given.

The inspection autofocus signal calculation unit 86 creates a graph by plotting a plurality of combinations of the AF signal and the focus evaluation value obtained for the inspection target substrate 101. Then, as shown in FIG. 12, the graph shape (template) indicated by the correlation data is fitted to the plotted results for the inspection target substrate 101. The template indicated by the correlation data is fitted to the graph of the plurality of plotted combinations so that the plurality of plotted combinations of the AF signal and the focus evaluation value obtained for the inspection target substrate 101 are positioned on the graph indicated by the correlation data.

Then, the inspection autofocus signal calculation unit 86 calculates the AF signal δm, for which the focus evaluation value is equal to or greater than a threshold value Thf, from the graph to which the template has been fitted. It is preferable that the threshold value Thf is set to, for example, 90% or more of the maximum value Cm′ of the fitted template. More preferably, the inspection autofocus signal calculation unit 86 calculates the AF signal δm for which the maximum value Cm′ of the fitted template is obtained. In other words, the inspection autofocus signal calculation unit 86 calculates the AF signal δm corresponding to the maximum value Cm′ of the fitted template. In this manner, it is possible to calculate the inspection AF signal δm for the inspection target substrate 101. The value of the inspection AF signal δm is stored in the storage device 51, for example.

In the image acquisition (autofocus control) step (S250), the optical image acquisition mechanism 150 captures an optical image of the substrate 101 by receiving light, which has been transmitted through or reflected from the substrate 101 irradiated with inspection light, with the imaging sensor 105 through the inspection optical system 175 while adjusting the height position of the pattern formation surface of the inspection target substrate 101 to the height position of the pattern formation surface corresponding to the value of the inspection autofocus signal δm. Specifically, the operation is as follows.

The optical image acquisition mechanism 150 scans the inspection stripe 20 of the inspection target substrate 101 with laser light (inspection light), thereby capturing a stripe region image with the imaging sensor 105 for each inspection stripe 20. Specifically, the operation is as follows. The XYθ table 102 is moved to a position where the inspection stripe 20, which is the target, can be imaged. In transmission inspection, laser light (for example, DUV light) having a wavelength in the ultraviolet region or shorter, which serves as inspection light, is emitted from the appropriate light source 103 and is directed to the transmission illumination optical system 170. The transmission illumination optical system 170 irradiates the pattern formed on the inspection target substrate 101 with the laser light. In other words, transmission illumination optical system 170 illuminates the inspection target substrate 101 on which the pattern is formed. The light transmitted through the inspection target substrate 101 passes through the magnification optical system 104 and the collimator lens 176, and is formed as an optical image on the imaging sensor 105 (an example of a sensor) and incident on it by the imaging optical system 178.

Alternatively, in reflection inspection, laser light (for example, DUV light) having a wavelength in the ultraviolet region or shorter, which serves as inspection light, is emitted from the appropriate light source 103 and is directed to the reflection illumination optical system 171. The reflection illumination optical system 171 irradiates the beam splitter 174 with the laser light. The irradiated laser light is reflected by the beam splitter 174 and the inspection target substrate 101 is irradiated with the laser light by the magnification optical system 104. The light reflected from the inspection target substrate 101 passes through the magnification optical system 104, the beam splitter 174, and the collimator lens 176, and is formed as an optical image on the imaging sensor 105 and incident on it by the imaging optical system 178.

When capturing such an optical image, the autofocus mechanism 131 adjusts the height position of the pattern formation surface of the inspection target substrate 101 to a height position hm of the pattern formation surface corresponding to the value δm of the inspection AF signal. In other words, the autofocus mechanism 131 adjusts the height position of the pattern formation surface of the substrate 101, which may change with the movement of the XYθ table 102 in the horizontal direction, to the height position hm corresponding to the inspection autofocus signal δm in a state where the inspection target substrate 101 is placed on the XYθ table 102. Specifically, the autofocus processing unit 66 receives the amount of light at the front focus position and the amount of light at the rear focus position from the light amount sensors 185 and 187, respectively, and calculates an AF signal z. Then, the Z drive mechanism 132 is controlled so that the AF signal z becomes δm.

Alternatively, it is also preferable to perform control using an offset. In such a case, the offset calculation unit 88 calculates, as an offset value z0, a difference obtained by subtracting zero from the inspection AF signal δm. Then, the autofocus processing unit 66 receives the amount of light at the front focus position and the amount of light at the rear focus position from the light amount sensors 185 and 187, respectively, and calculates the AF signal z. Then, the autofocus processing unit 66 outputs, to the Z drive mechanism 132, a value obtained by subtracting the offset value z0 from the calculated AF signal z. The Z drive mechanism 132 adjusts the mask surface height position so that the value obtained by subtracting the offset value z0 from the calculated AF signal z becomes zero.

The imaging sensor 105 captures an optical image of the inspection target substrate 101 by receiving light, which has been transmitted through or reflected from the inspection target substrate 101 irradiated with inspection light, in a state where the height position of the pattern formation surface of the inspection target substrate 101 has been adjusted to the height position of the pattern formation surface corresponding to the value of the inspection AF signal δm.

The image of the pattern formed on the imaging sensor 105 is photoelectrically converted by each photosensor element of the imaging sensor 105, and is further A/D (analog-to-digital) converted by the sensor circuit 106. Then, pixel value data of the inspection stripe 20 to be measured is stored in the stripe pattern memory 123. The measurement data (pixel data) is, for example, 8-bit unsigned data, and represents the brightness gradation (amount of light) of each pixel.

On the other hand, the reference image generation circuit 112 generates a reference image to be used as a reference, using the figure pattern data (design data). The reference image is generated for each inspection stripe 20 of the inspection target substrate 101 in parallel with the scanning operation of the inspection stripe 20. Specifically, the operation is as follows. The reference image generation circuit 112 receives figure pattern data (design data) for each frame region 30 of the inspection stripe 20 as a target, and converts each figure pattern defined in the figure pattern data into binary or multi-value image data.

The figure patterns defined in the figure pattern data are basic figures such as a rectangle and a triangle. For example, figure pattern data is stored in which the shape, size, position, and the like of each figure are defined by information such as coordinates (x, y) at a reference position of the figure, side lengths, and a figure code serving as an identifier for identifying the figure type such as a rectangle and a triangle.

When such design pattern data serving as figure pattern data is input to the reference image generation circuit 112, the data is expanded into data for each figure, and the figure code indicating the figure shape, figure dimensions, and the like of each piece of figure data are interpreted. Then, the data is expanded into binary or multi-value design pattern image data as patterns arranged within a grid of squares with a predetermined quantization size as a unit, and then output. In other words, the design data is loaded, the frame region is virtually divided into squares with a predetermined size as a unit, the occupancy rate of the figures in the design pattern is calculated for each square, and n-bit occupancy rate data (design image data) is output. For example, it is preferable to set one square as one pixel. Then, assuming that one pixel has a resolution of ½⁸ (= 1/256), 1/256-sized small regions corresponding to the region of the figure arranged within the pixel are allocated, and the occupancy rate within the pixel is calculated. Then, the result is generated as 8-bit occupancy rate data. Such squares (inspection pixels) may be aligned with the pixels of the measurement data.

Then, the reference image generation circuit 112 performs filter processing on the design image data of the design pattern, which is image data of the figure, using a filter function.

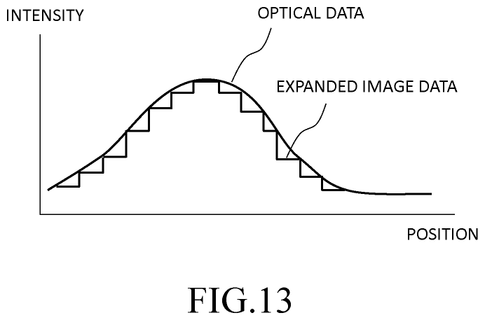

FIG. 13 is a diagram for explaining the filter processing in Embodiment 1. The pixel data of the optical image captured from the inspection target substrate 101 is in a state where a filter has been applied due to the resolution characteristics of the optical system used for imaging, in other words, in a continuously changing analog state. Therefore, for example, as shown in FIG. 13, the image intensity (gray-scale value) is different from the expanded image (design image) having digital values. On the other hand, as described above, the figure pattern data is defined by the figure code or the like. Therefore, in the expanded design image, the image intensity (gray-scale value) may be a digital value. For this reason, the reference image generation circuit 112 performs image processing (filter processing) on the expanded image to generate a reference image that is closer to the optical image. As a result, the design image data, which is design-side image data having an image intensity (gray-scale value) being a digital value, can be matched to the image generation characteristics of the measurement data (optical image). The generated reference image is output to the comparison circuit 108.

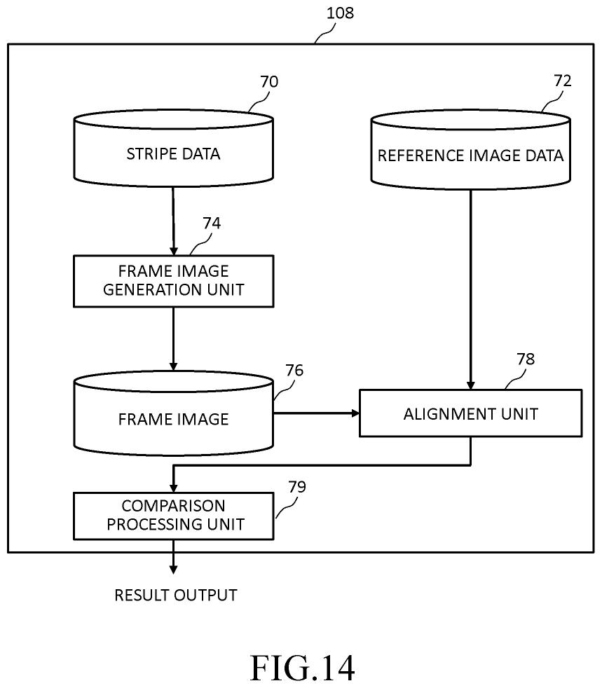

FIG. 14 is a diagram showing an example of the internal configuration of a comparison circuit in Embodiment 1. In FIG. 14, storage devices 70, 72, and 76 such as magnetic disk drives, a frame image generation unit 74, an alignment unit 78, and a comparison processing unit 79 are arranged in the comparison circuit 108. A series of “~ units”, such as the frame image generation unit 74, the alignment unit 78, and the comparison processing unit 79, each includes a processing circuit. Examples of such a processing circuit include an electric circuit, a computer, a processor, a circuit board, a quantum circuit, and a semiconductor device. In addition, for the respective “~ units”, a common processing circuit (the same processing circuit) may be used. Alternatively, different processing circuits (separate processing circuits) may be used. Input data required for the frame image generation unit 74, the alignment unit 78, and the comparison processing unit 79 or calculation results thereof are stored, as needed, in a memory (not shown) within the comparison circuit 108 or in the memory 111.

The stripe data (stripe region image) input to the comparison circuit 108 is stored in the storage device 70. The reference image data input to the comparison circuit 108 is stored in the storage device 72.

In the comparison step (S252), the comparison circuit 108 (an example of a comparison unit) compares the captured optical image with a reference image and outputs the result. Specifically, the operation is as follows.

In the comparison circuit 108, first, the frame image generation unit 74 generates a plurality of frame images 31 by dividing the stripe region image (optical image) by a predetermined width. Specifically, as shown in FIG. 2, the stripe region image is divided into frame images of a plurality of rectangular frame regions 30. For example, the stripe region image is divided into frame images each having a size of 512×512 pixels. The data of each frame region 30 is stored in the storage device 76.

Then, the alignment unit 78 reads the corresponding frame image 31 and the corresponding reference image from the storage devices 72 and 76 for each frame region 30, and performs alignment between the frame image 31 and the corresponding reference image using a predetermined algorithm. For example, alignment is performed using a least squares method.

Then, the comparison processing unit 79 (another example of a comparison unit) compares the frame image 31 with the reference image corresponding to the frame image 31. For example, comparison is performed for each pixel. Here, the two images are compared for each pixel in accordance with predetermined determination conditions to determine whether or not there is a defect, such as a shape defect. As the determination conditions, for example, the two images are compared for each pixel according to a predetermined algorithm to determine whether or not there is a defect. For example, a difference value between the pixel values of the two images is calculated for each pixel, and a case where the difference value is greater than a threshold value Th is determined to be a defect. Then, the comparison results may be output to, for example, the magnetic disk drive 109, the magnetic tape drive 115, the flexible disk drive (FD) 116, the CRT 117, and the pattern monitor 118, or may be output from the printer 119.

In the above example, the case of die-to-database inspection has been described, but die-to-die inspection may also be used. In such a case, among the plurality of frame regions 30, for frame regions on which the die-to-die inspection is performed, the comparison circuit 108 uses, as a reference (reference image), a frame image (optical image) of die 2 acquired for one of the frame regions. First, for each frame region 30 on which the die-to-die inspection is performed, the alignment unit 78 reads a corresponding frame image 31 of die 1 and a frame image of die 2 from the storage device 76, and performs alignment between the frame image 31 of die 1 and the frame image of die 2 using a predetermined algorithm. For example, alignment is performed using a least squares method. Then, the comparison processing unit 79 (comparison unit) compares the corresponding frame image 31 of die 1 with the corresponding frame image of die 2 for each pixel for each frame region 30 where the die-to-die inspection is performed.

As described above, according to Embodiment 1, parameters necessary for the autofocus operation of the inspection target substrate 101 can be acquired in a shorter time than in the related art.

Conventionally, in order to precisely calculate the AF signal at which the focus evaluation value becomes maximum, it has been necessary to perform “changes in focus evaluation value with respect to changes in AF signal” at many sample points (10 points or more). On the other hand, according to Embodiment 1, since the template creation step using the evaluation substrate described in FIG. 11 only needs to be performed once when the apparatus is started up (this is not included in the inspection time), it is possible to acquire a precise template curve after collecting many sample points (10 points or more, with no time limitation). When inspecting the inspection target substrate, it is sufficient to take, for example, three sample points as a minimum required number and fit these to the template. Therefore, according to Embodiment 1, the time required for the process of acquiring the parameters necessary for the autofocus operation can be reduced to, for example, 3/10=30%. This can be further reduced depending on the number of measurement points.

The embodiments have been described above with reference to specific examples. However, the invention is not limited to these specific examples.

In addition, the description of parts that are not directly required for the description of the invention, such as the apparatus configuration or the control method, has been omitted. However, the required apparatus configuration, control method, and the like can be appropriately selected and used. For example, although the description of the control unit configuration for controlling the inspection apparatus 100 has been omitted, it is needless to say that the required control unit configuration can be appropriately selected and used.

In addition, all pattern inspection apparatuses, focus position adjustment methods, and pattern inspection methods that include the elements of the invention and can be appropriately redesigned by those skilled in the art are included in the scope of the invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern inspection apparatus, comprising:
a stage, a substrate being placed on the stage;
a drive mechanism configured to move a height position of the stage;
a correlation data creation circuit configured to create, using an autofocus signal used as a parameter for autofocus control for each height position and a focus evaluation value for evaluating a focus position for the each height position, correlation data between the autofocus signal and the focus evaluation value, the autofocus signal and the focus evaluation value being acquired while changing a height position of a pattern formation surface of an evaluation substrate formed with an evaluation pattern with the evaluation substrate placed on the stage;
a storage device configured to store the correlation data;
an inspection autofocus signal calculation circuit configured to calculate an inspection autofocus signal for acquiring a focus evaluation value equal to or greater than a threshold value for an inspection target substrate formed with a figure pattern, using the autofocus signal and the focus evaluation value for each height position acquired while changing a height position of a pattern formation surface of the inspection target substrate with the inspection target substrate placed on the stage and the correlation data obtained from the evaluation substrate;
an autofocus mechanism configured to adjust the height position of the pattern formation surface of the inspection target substrate to a height position of the pattern formation surface corresponding to a value of the inspection autofocus signal;
a sensor configured to capture an optical image of the inspection target substrate by receiving light transmitted through or reflected from the inspection target substrate irradiated with inspection light in a state where the height position of the pattern formation surface of the inspection target substrate has been adjusted to the height position of the pattern formation surface corresponding to the value of the inspection autofocus signal; and
a comparison circuit configured to compare a captured optical image with a reference image.

2. The apparatus according to claim 1,
wherein, as the correlation data, a function obtained by approximating the autofocus signal and the focus evaluation value for each height position is used.

3. The apparatus according to claim 1,
wherein, as the correlation data, a numerical sequence of the autofocus signal and the focus evaluation value for each height position is used.

4. The apparatus according to claim 1,
wherein the autofocus signal and the focus evaluation value for each height position of the inspection target substrate are acquired at three or more different height positions.

5. The apparatus according to claim 1,
wherein the correlation data creation circuit includes:
a plot processing circuit configured to plot the focus evaluation value for each autofocus signal acquired for each height position; and
a fitting processing circuit configured to approximate the plotted focus evaluation value for each autofocus signal value using a convex polynomial function.

6. The apparatus according to claim 1,
wherein the inspection autofocus signal calculation circuit creates a graph by plotting a plurality of combinations of the autofocus signal and the focus evaluation value obtained for the inspection target substrate, and fits a template indicated by the correlation data to the plurality of plotted combinations.

7. The apparatus according to claim 6,
wherein the inspection autofocus signal calculation circuit calculates an inspection autofocus signal for acquiring a focus evaluation value equal to or greater than a threshold value from the graph, the template has been fitted to the graph.

8. The apparatus according to claim 7,
wherein the inspection autofocus signal calculation circuit calculates the inspection autofocus signal corresponding to a maximum value of the fitted template.

9. A focus position adjustment method, comprising:
creating, using an autofocus signal used as a parameter for autofocus control for each height position and a focus evaluation value for evaluating a focus position for the each height position, correlation data between the autofocus signal and the focus evaluation value, the autofocus signal and the focus evaluation value being acquired while changing a height position of a pattern formation surface of an evaluation substrate formed with an evaluation pattern with the evaluation substrate placed on the stage;
storing the correlation data in a storage device;
calculating an inspection autofocus signal for acquiring a focus evaluation value equal to or greater than a threshold value for an inspection target substrate formed with a figure pattern, using the autofocus signal and the focus evaluation value for each height position acquired while changing a height position of a pattern formation surface of the inspection target substrate with the inspection target substrate placed on the stage and the correlation data obtained from the evaluation substrate; and
adjusting, in a case of capturing an optical image of the inspection target substrate with a sensor by receiving light transmitted through or reflected from the inspection target substrate irradiated with inspection light, the height position of the pattern formation surface of the inspection target substrate to a height position of the pattern formation surface corresponding to a value of the inspection autofocus signal.

10. A pattern inspection method, comprising:
creating, using an autofocus signal used as a parameter for autofocus control for each height position and a focus evaluation value for evaluating a focus position for each height position, correlation data between the autofocus signal and the focus evaluation value, the autofocus signal and the focus evaluation value being acquired while changing a height position of a pattern formation surface of an evaluation substrate formed with an evaluation pattern with the evaluation substrate placed on the stage;
storing the correlation data in a storage device;
calculating an inspection autofocus signal for acquiring a focus evaluation value equal to or greater than a threshold value for an inspection target substrate formed with a figure pattern, using the autofocus signal and the focus evaluation value for each height position acquired while changing a height position of a pattern formation surface of the inspection target substrate with the inspection target substrate placed on the stage and the correlation data obtained from the evaluation substrate;
capturing an optical image of the inspection target substrate with a sensor by receiving light transmitted through or reflected from the inspection target substrate irradiated with inspection light while adjusting the height position of the pattern formation surface of the inspection target substrate to a height position of the pattern formation surface corresponding to a value of the inspection autofocus signal; and
comparing a captured optical image with a reference image and outputting a result of the comparison.
